(19) United States
(12) Patent Application Publication
(10) Pub. No.: US 2021/0173970 A1
(43) Pub. Date: Jun. 10, 2021

(54) SYSTEMS FOR GENERATING SINGULAR AUTOMATED CAPACITY MODELS

(71) Applicant: BANK OF AMERICA CORPORATION, Charlotte, NC (US)

(72) Inventors: Karthik Srinivasan, Chatsworth, CA (US); Bhanu Bandi, Plano, TX (US); Rupesh Kotecha, Chino Hills, CA (US); Teodora Ana Maria Stoica, Carrollton, TX (US)

(73) Assignee: BANK OF AMERICA CORPORATION, Charlotte, NC (US)

(21) Appl. No.: 16/708,810

(22) Filed: Dec. 10, 2019

(51) Int. Cl. G06F 30/20

(52) U.S. Cl. CPC G06F 30/20

(57) ABSTRACT

A system for end-to-end automated generation of resource capacity models. The system is integrated with process management systems, such that when a change to specified process occurs it triggers the generation of a new or updated resource capacity model. In addition, the system is integrated with multiple different data sources/applications, such that, once generation of a resource capacity model is triggered automated data feeds from the multiple data source/application occur and the system compiles and/or aggregates the data to create the resulting resource capacity models. Such data source/applications may include, but are not limited to, measurable attributes associated with the process, processor data and taxonomy data that classify tasks included with the overall process. Moreover, the system is integrated with medium of exchange data systems, such that the resource capacity models may include forecasted medium of exchange volumes required to perform the process. Additionally, the system is modularized by entities within an enterprise to provide consistency at the entity-level.

### FIELD OF THE INVENTION

The present invention is generally related to computing technologies and, more specifically, computing systems for generating singular automated processor resource capacity models.

### BRIEF SUMMARY

The following presents a simplified summary of one or more embodiments of the invention in order to provide a basic understanding of such embodiments. This summary is not an extensive overview of all contemplated embodiments and is intended to neither identify key or critical elements of all embodiments, nor delineate the scope of any or all embodiments. Its sole purpose is to present some concepts of one or more embodiments in a simplified form as a prelude to the more detailed description that is presented later.

Embodiments of the present invention address the above needs and/or achieve other advantages by providing for an end-to-end automated system for generating resource capacity models. The system is integrated with process management systems, such that when a change to specified process occurs (i.e., a new process is added, or an existing process is modified) it triggers the generation of a new or updated capacity model. In addition, the system is in network connection with multiple different data sources/applications, such that, once generation of a resource capacity model is triggered automated data feeds from the multiple data source/application occur and the system compiles and/or aggregates the data to create the resulting resource capacity models. Such data source/applications may include, but are not limited to, measurable attributes associated with the process, processor data and taxonomy data that classify tasks (e.g., sub-processes, activities or the like) included with the overall process.

Moreover, the system provides for a modularized approach to generating resource capacity models, such that individual resource capacity model functionality exists for different entities within an enterprise. As result, consistency amongst the resource capacity models is realized at the entity-level.

In addition, the system is integrated with medium of exchange data that assigns processors with medium of exchange volumes required to perform the tasks within the process, such that the resource capacity model can include medium of exchange forecasts required to perform the process.

In addition, the present invention provides complete transparency to the resource capacity model process, in that, portals/hubs are provided for presenting user interfaces that include the resource capacity models and reports are generated and disseminated to requisite parties. Further, the user interfaces and/or reports are configured to provide access, through hyperlinks or the like, to the data used to generate the resource capacity models, thereby providing the user with insight into how and why the resource capacity model was generated.

A system for generating singular automated resource capacity models defines first embodiments of the invention. The system includes at least one process management sub-system including a first memory and at least one first processor in communication with the first memory. The first memory stores a plurality of predetermined processes and first instructions. The first instructions are executable by the at least one first processor and configured to manage changes to the plurality of predetermined processes. The system additionally includes a resource capacity model generator sub-system which is in network communication with the at least one process management sub-system. The process resource capacity model generator sub-system includes a second memory and at least one second processor in communication with the second memory. The second memory stores second instructions configured to receive, from one of the process management sub-system(s), a notification of a change to one of the processes (i.e., addition of a new process, or modification of an existing process) and, in response, receive automated feeds of (i) measurable attribute data associated with the process, (ii) processor data associated with processors required to perform the process, and (iii) taxonomy data that classifies tasks associated with the process. In addition, the second instructions are further configured to update or generate one or more resource capacity models for the process based at least on the measurable attribute data, the processor data and the taxonomy data. The resource capacity models forecast processor capacity for performing the process during at least one processing period.

In specific embodiments the system further includes a processor resource assignment sub-system that is in network communication with the processor resource capacity model generator sub-system. The processor resource assignment subsystem includes a third memory configured to store medium of exchange data that assign processors with an amount of resources required to perform tasks included within the process. In related embodiments of the system, the second instructions are further configured to receive an automated feed from the processor resource assignment sub-system of medium of exchange data associated with the process, and determine at least one medium of exchange volume forecast for each of the one or more resource capacity models based at least on the medium of exchange data.

In further specific embodiments of the system, the second instructions are further configured to generate user interfaces, and/or electronic reports. The user interfaces and electronic reports are configured to present the one or more updated or generated resource capacity models. In related embodiments of the system, the user interfaces and the electronic reports are further configured to provide access to (i) the measurable attribute data, (ii) the processor data, and (iii) the taxonomy data used as a basis for updating or generating the one or more resource capacity models.

In other specific embodiments of the system, the second instructions are further configured to, in response to receiving the notification, receive inputs that define one or more dimensions for the one or more resource capacity models, and update or generate the one or more resource capacity models for the process based further on the one or more dimensions. In such embodiments of the system, the one or more dimensions may include, but are not limited to, at least one of (i) geo-physical location of the process, (ii) entity associated with the process, and (iii) computing platform associated with the process.

In other specific embodiments of the system, the second instructions configured to receive automated feeds of (i) the measurable attribute data associated with the process further define the measurable attribute data as including, but not limited to, a volume of at least one of the process or one or more of the tasks included within the process occurring within predetermined time interval(s).

In additional specific embodiments of the system, the second instructions configured to receive automated feeds of (ii) the processor data associated with the processors required to perform the process further define the processor data as including, but not limited to, at least one of (a) processor summary data that define functionality of processors, (b) at least one of a volume of processors or level of processors required to perform a task included within the process, and (c) resource hierarchy data that defines a resource rate for processors.

In other specific embodiments of the system, the processor resource capacity model generator sub-system is modularized so as to receive the automated feeds of (i) the measurable attribute data (ii) the processor data and (iii) the taxonomy data from a plurality of entity systems associated with at least one of the process or the data. In addition, the modularized nature of the processor resource capacity model generator sub-system provides for new and/or additional entity systems to be readily integrated with the processor resource capacity model generator sub-system as new or additional data is needed in order to generate/update the resource capacity models.

In other specific embodiments of the system, the resource capacity models that are updated and generated may include, but are not limited to, a best-case resource capacity model (e.g., least amount of processors) and a worst-case resource capacity model (e.g., greatest amount of processors).

A computer-implemented method for generating singular automated resource capacity models defines second embodiments of the invention. The method is implemented by one or more computing processor devices. The method includes receiving a notification of a change (i.e., addition of a new process, or modification of an existing process) to one of plurality of predetermined processes and, in response, receiving automated feeds of (i) measurable attribute data associated with the process, (ii) processor data associated with processors required to perform the process, and (iii) taxonomy data that classifies tasks associated with the process. In addition, the method includes updating or generating one or more resource capacity models for the process based at least on the measurable attribute data, the processor data and the taxonomy data. The resource capacity models forecast processor capacity for performing the process during at least one processing period.

In specific embodiments the computer-implemented method further includes receiving an automated feed of medium of exchange data associated with the process, and determining at least one medium of exchange volume forecast for each of the one or more resource capacity models based at least on the medium of exchange data.

In other specific embodiments the computer-implemented method further included generating user interfaces, and/or electronic reports, which are configured to present the one or more updated or generated resource capacity models and provide access to (i) the measurable attribute data, (ii) the processor data, and (iii) the taxonomy data used as a basis for updating or generating the one or more resource capacity models.

In other specific embodiments the computer-implemented method further includes, in response to receiving the notification, receiving inputs that define one or more dimensions for the one or more resource capacity models, and updating or generating the one or more resource capacity models for the process based further on the one or more dimensions. In such embodiments of the invention, the one or more dimensions include, but are not limited to, at least one of (i) geo-physical location of the process, (ii) entity associated with the process, and (iii) computing platform associated with the process.

In still further specific embodiments of the computer-implemented method, receiving automated feeds of (ii) the processor data associated with the processors required to perform the process define the processor data as including, but not limited to, at least one of (a) processor summary data that define functionality of processors, (b) at least one of a volume of processors or level of processors required to perform a task included within the process, and (c) resource hierarchy data that defines a resource rate for processors.

A computer program product including a non-transitory computer-readable medium defines third embodiments of the invention. The computer-readable medium includes a first set of codes for causing a computer to receive a notification of a change to a process from amongst the plurality of predetermined processes. The computer-readable medium includes a second set of codes for causing a computer to, in response to receiving the notification, receive automated feeds of (i) measurable attribute data associated with the process, (ii) processor data associated with processors required to perform the process, and (iii) taxonomy data that classifies tasks associated with the process. Further, the computer-readable medium includes a third set of codes for causing a computer to update or generate one or more resource capacity models for the process based at least on the measurable attribute data, the processor data and the taxonomy data. The resource capacity models forecast processor capacity for performing the process during at least one processing period.

In specific embodiments of the computer program product, the computer-readable medium additionally includes a fourth set of codes for causing a computer to receive an automated feed of medium of exchange data associated with the process, and a fifth set of codes for causing a computer to determine at least one medium of exchange volume forecast for each of the one or more resource capacity models based at least on the medium of exchange data.

In other specific embodiments of the computer program product, the computer readable medium includes a fourth set of codes for causing a computer to generate at least one of user interfaces, and electronic reports that are configured to preset the one or more updated or generated resource capacity models and provide access to (i) the measurable attribute data, (ii) the processor data, and (iii) the taxonomy data used as a basis for updating or generating the one or more resource capacity models.

In still further specific embodiments of the computer program product, computer-readable medium further includes a fourth set of codes for causing a computer to, in response to receiving the notification, receive inputs that define one or more dimensions for the one or more resource capacity models. In such embodiments of the computer program product, the third set of codes is further configured to update or generate the one or more resource capacity models for the process based further on the one or more dimensions. Moreover, in such embodiments, the one or more dimensions include, but are not limited to, at least one of (i) geo-physical location of the process, (ii) entity associated with the process, and (iii) computing platform associated with the process.

Further, in other specific embodiments of the computer program product, the second set of codes is further configured to receive automated feeds of (ii) the processor data defines including, but not limited to, at least one of (a) processor summary data that define functionality of processors, (b) at least one of a volume of processors or level of processors required to perform a task included within the process, and (c) resource hierarchy data that defines a resource rate for processors.

Thus, according to embodiments of the invention, which will be discussed in greater detail below, the present invention provides for end-to-end automated generation of resource capacity models. The system is integrated with process management systems, such that when a change to specified process occurs it triggers the generation of a new or updated capacity model. In addition, the system is integrated with multiple different data sources/applications, such that, once generation of a resource capacity model is triggered automated data feeds from the multiple data source/application occur and the system compiles and/or aggregates the data to create the resulting resource capacity models. Such data source/applications may include, but are not limited to, measurable attributes associated with the process, processor data and taxonomy data that classify tasks included with the overall process.

The features, functions, and advantages that have been discussed may be achieved independently in various embodiments of the present invention or may be combined with yet other embodiments, further details of which can be seen with reference to the following description and drawings.

### BRIEF DESCRIPTION OF THE DRAWINGS

Having thus described embodiments of the disclosure in general terms, reference will now be made to the accompanying drawings, wherein:

FIG. 1 is a schematic/block diagram of a system for generating singular automated resource capacity models, in accordance with embodiments of the present invention;

FIG. 2 is a block diagram of a system for generating singular automated resource capacity models, in accordance with some embodiments of the present disclosure;

FIG. 3 is a block diagram of a resource capacity model generator sub-system, in accordance with embodiments of the present invention; and

FIG. 4 is a flow diagram of a method for generating singular automated resource capacity models, in accordance with embodiments of the present invention.

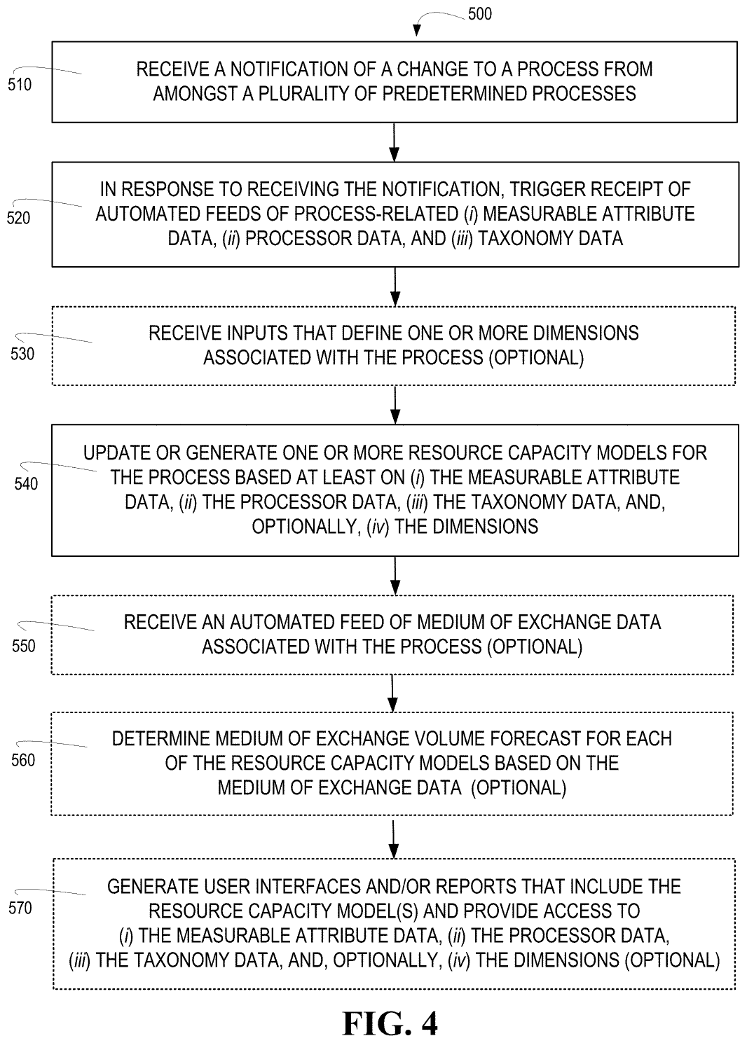

### DETAILED DESCRIPTION OF EMBODIMENTS OF THE INVENTION

Embodiments of the present invention will now be described more fully hereinafter with reference to the accompanying drawings, in which some, but not all, embodiments of the invention are shown. Indeed, the invention may be embodied in many different forms and should not be construed as limited to the embodiments set forth herein; rather, these embodiments are provided so that this disclosure will satisfy applicable legal requirements. Like numbers refer to like elements throughout.

As will be appreciated by one of skill in the art in view of this disclosure, the present invention may be embodied as a system, a method, a computer program product or a combination of the foregoing. Accordingly, embodiments of the present invention may take the form of an entirely hardware embodiment, an entirely software embodiment (including firmware, resident software, micro-code, etc.), or an embodiment combining software and hardware aspects that may generally be referred to herein as a “system.” Furthermore, embodiments of the present invention may take the form of a computer program product comprising a computer-usable storage medium having computer-usable program code/computer-readable instructions embodied in the medium.

Any suitable computer-usable or computer-readable medium may be utilized. The computer usable or computer-readable medium may be, for example but not limited to, an electronic, magnetic, optical, electromagnetic, infrared, or semiconductor system, apparatus, or device. More specific examples (e.g., a non-exhaustive list) of the computer-readable medium would include the following: an electrical connection having one or more wires; a tangible medium such as a portable computer diskette, a hard disk, a time-dependent access memory (RAM), a read-only memory (ROM), an erasable programmable read-only memory (EPROM or Flash memory), a compact disc read-only memory (CD-ROM), or other tangible optical or magnetic storage device.

Computer program code/computer-readable instructions for carrying out operations of embodiments of the present invention may be written in an object oriented, scripted or unscripted programming language such as JAVA, PERL, SMALLTALK, C++, PYTHON or the like. However, the computer program code/computer-readable instructions for carrying out operations of the invention may also be written in conventional procedural programming languages, such as the “C” programming language or similar programming languages.

Embodiments of the present invention are described below with reference to flowchart illustrations and/or block diagrams of methods or systems. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a particular machine, such that the instructions, which execute by the processor of the computer or other programmable data processing apparatus, create mechanisms for implementing the functions/acts specified in the flowchart and/or block diagram block or blocks.

These computer program instructions may also be stored in a computer-readable memory that can direct a computer or other programmable data processing apparatus to function in a particular manner, such that the instructions stored in the computer-readable memory produce an article of manufacture including instructions, which implement the function/act specified in the flowchart and/or block diagram block or blocks.

The computer program instructions may also be loaded onto a computer or other programmable data processing apparatus to cause a series of operational events to be performed on the computer or other programmable apparatus to produce a computer implemented process such that the instructions, which execute on the computer or other programmable apparatus, provide events for implementing the functions/acts specified in the flowchart and/or block diagram block or blocks. Alternatively, computer program implemented events or acts may be combined with operator or human implemented events or acts in order to carry out an embodiment of the invention.

As the phrase is used herein, a processor may be “configured to” perform or “configured for” performing a certain function in a variety of ways, including, for example, by having one or more general-purpose circuits perform the function by executing particular computer-executable program code embodied in computer-readable medium, and/or by having one or more application-specific circuits perform the function.

Thus, according to embodiments of the invention, which will be described in more detail below, systems, methods and computer program products are disclosed that provide for an end-to-end automated system for generating resource capacity models. The system is integrated with process management systems, such that when a change to specified process occurs (i.e., a new process is added, or an existing process is modified) it triggers the generation of a new or updated capacity model. In addition, the system is in network connection with multiple different data sources/applications, such that, once generation of a resource capacity model is triggered automated data feeds from the multiple data source/application occur and the system compiles and/or aggregates the data to create the resulting resource capacity models. Such data source/applications may include, but are not limited to, measurable attributes associated with the process, processor (i.e., employee, associate) data and taxonomy data that classify tasks (e.g., sub-processes, activities or the like) included with the overall process.

A resource capacity model is a tool used to forecast the volume of work to be performed in the future. In this regard, resource capacity models serve to forecast the resources (i.e., software, hardware, manpower and associated costs) required to perform a specific process for a specified period of time.

Typically, resource capacity models are managed through conventional spreadsheets. However, even within one enterprise, different forms of spreadsheets may be used to manage resource capacity models and different levels of automation may be implemented in creating the resource capacity models. Moreover, resource capacity models resulting from spreadsheet-based systems lack consistency within an enterprise, since the data that is relied upon to create the resource capacity models is maintained and managed inconsistently across different entities within the enterprise.

In addition, the system of the present invention provides for a modularized approach to generating resource capacity models, such that individual resource capacity model functionality exists for different entities within an enterprise. As result, consistency amongst the resource capacity models is realized at the entity-level.

Additionally, the system of the present invention is integrated with medium of exchange (i.e., financial) data that assigns processors with medium of exchange amounts (i.e., cost) required to perform the tasks within the process, such that the resource capacity model can include medium of exchange forecasts required to perform the process.

Moreover, the present invention provides complete transparency to the resource capacity model generation process, in that, portals/hubs are provided for presenting user interfaces and reports are generated and disseminated to requisite parties that no only include the resource capacity models but also provide access, through hyperlinks or the like, to the data used to generate the resource capacity models, thereby providing the user with insight into how and why the resource capacity model was generated.

As a result the present invention provides for a highly consistent and automated means for generating resource capacity models. Specifically, the present invention provides for connection to various data sources within an enterprise, such that when a resource capacity model is deemed necessary, automated data feeds can be provided to generate the resource capacity model. Moreover, new or different data sources can be efficiently integrated into the resource capacity model generator as deemed necessary.

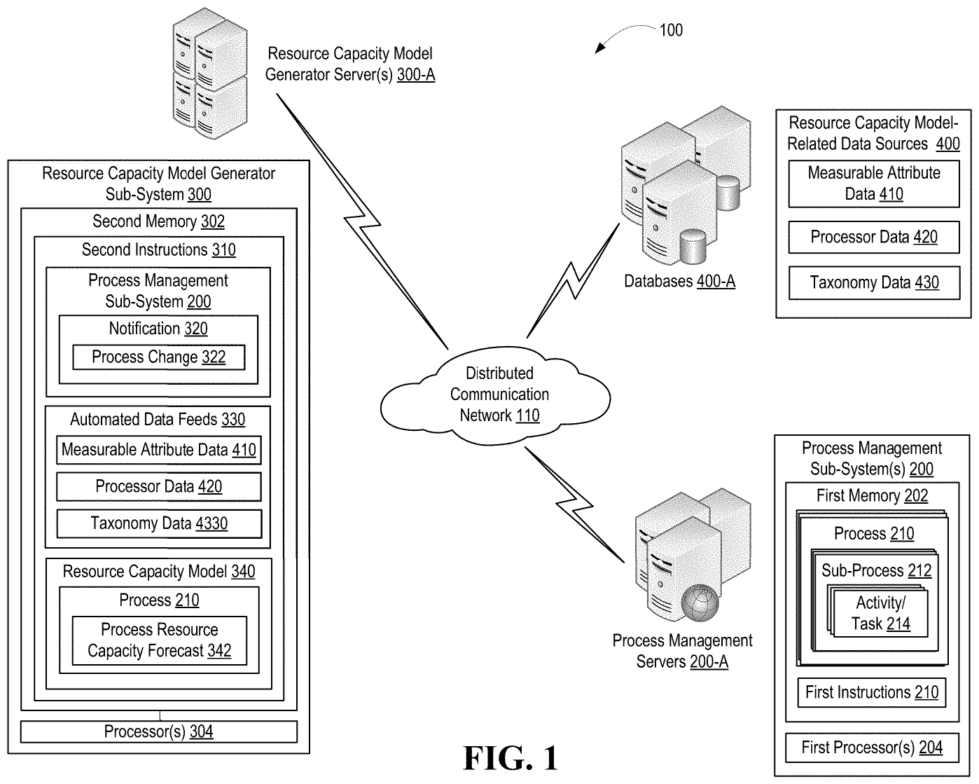

Referring to FIG. 1, a schematic diagram is depicted of a system 100 for generating singular automated resource capacity models, in accordance with embodiments of the present invention. The system 100 is implemented in a distributed communication network 110, which may include one or more intranets and/or the Internet or the like. The system 100 includes one or more process management sub-systems 200 implemented via one or more process management servers 200-A and/or other applicable computing devices. In specific embodiments of the system, an enterprise may implement more than one process management sub-systems 200. For example, specific entities (e.g., business units, frontline units or the like) may rely on different process management sub-systems 200 as a means for controlling their specific processes/workflows.

The process management sub-system 200 includes a first memory 202 and one or more first processors 204 in communication with the memory 202. The first memory 202 stores a plurality of predetermined processes 210 that include one or more sub-processes 212 and/or activities/tasks 214. A process, as used herein, is a series of activities/tasks that work in unison to define workflow. In specific embodiments of the invention the predetermined processes 210 may be processes identified by an enterprise or individual entities (e.g., business units, frontline units or the like) within an enterprise as having heightened importance or requiring operational excellence. For example, in specific enterprises, each individual entity may identify certain processes as instrumental in conducting the entity's business or the like. First memory 202 additionally stores first instructions 210 that are executable by the first processor(s) 204 and configured to manage changes to the plurality of predetermined processes 210. Change to a predetermined process may include a modification/update to a preexisting predetermined process 210 or addition of a new predetermined process 210. In addition, first instructions 210 include governance rules that are applied to the management of changes to the predetermined processes 210, such as, what changes are authorized, how and when changes can occur, who is authorized to make changes and the like.

System 100 additionally includes resource capacity model generator sub-system 300 that is implemented via resource capacity model generator server(s) 300-A and/or other applicable computing devices. In specific embodiments of the system, the resource capacity model generator sub-system is a modularized sub-system to accommodate different entities (e.g., business units, frontline units or the like). As previously discussed, each entity may implement different process management sub-systems 200 and, as discussed infra., different data and/or data sources, therefore, modularization within the resource capacity model generator sub-system 300 accommodates such differences while maintaining consistency amongst the resource capacity models.

Resource capacity model generator sub-system 300 includes second memory 302 and one or more processors 304 in communication with the second memory 302. The memory 302 stores second instructions 310 that are executable by the one or more second processors 304. The resource capacity model generator sub-system 300 is in network communication with process management sub-system 200, such that when a change to process occurs, the change triggers process management sub-system 200 to communicate a notification/signal 320 to the resource capacity model generator sub-system 300. Second instructions 310 receives the notification/signal 320 of the process change 322 to one of the processes 210, which triggers second instructions 310 to generate a resource capacity model 340.

In this regard, in response to receiving the notification 320, second instructions receive automated data feeds 330 from capacity model-related data sources 400, such as databases 400 and/or other storage devices. In specific embodiments of the invention, the second instructions 310 may be configured to communicate data requests to the various data sources 400, while in other embodiments of the invention, the first instructions 210 of the process management sub-system(s) 200 may be configured to notify the various data sources 400 of the process change 322, which in turn triggers the data sources 400 to compile and communicate the requisite data to the resource capacity model generator sub-system 300 in an associated automated data feed 330. The data feeds 330 are configured to include measurable attribute data 410 associated with the process. In specific embodiments of the system, the measurable attribute data 410, otherwise referred to as process driver data, includes, but is not limited to, volume-related data that indicates the volume of occurrences of a process 210 and/or sub-processes 212, tasks/activities 214 or other function associated with the process, occurring over a predetermined time period (e.g., hour, day, week or the like).

Further, the data feeds 330 are configured to include processor (e.g., employee, associate or the like) data 420 or the like associated with processors required to perform the process 210 and/or sub-processes 212, activities/tasks 214 and the like. As discussed in more detail infra., processor data 420 may include, but is not limited to, processor summary data, processor hierarchy data and processor function data. Additionally, data feeds 330 are configured to include taxonomy data 430 that classifies the various sub-processes 212 and tasks/activities 214 included within a process 210 as a means of normalizing the sub-processes 212 and/or task/activities 210 required to perform the process 210.

In addition, second instructions 310 are configured to aggregate at least the measurable attribute data 410, the processor data 420 and the taxonomy data 430 to update an existing resource capacity model 340 or generate a new resource capacity model 340 that includes a process capacity forecast 342 for one or more future periods of time. The process capacity forecast 342 may include a forecast of the processors necessary to perform the forecasted process capacity.

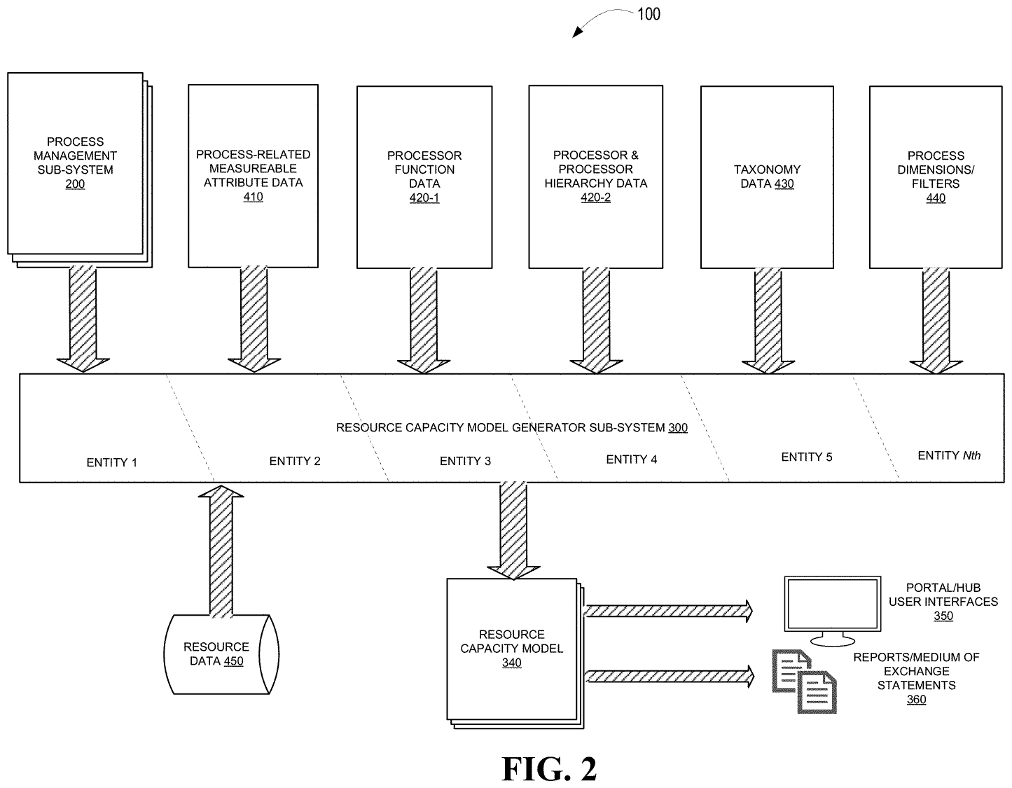

Referring to FIG. 2, a schematic diagram is provided of the system 100 for generating singular automated resource capacity models, in accordance with alternative embodiments of the invention. Specifically, FIG. 2 describes additional optional features of the system 100 that were not described in relation to FIG. 1.

As previously discussed, the resource capacity model generator sub-system 300 is in network communication with one or more process management sub-systems 200, which store predetermined process and provide for the management of change to such processes. The process management sub-systems 200 utilized within an enterprise may vary based on which entity's (i.e., business unit, frontline unit or the like) processes are being managed. However, the modular nature of the resource capacity model generator sub-system 300 allows for the different process management sub-systems 200 to integrate with the resource capacity model generator sub-system 300. In addition, each process management sub-system 200 includes applicable change management governance rules that serve to control the process change management procedure. In response to a change to one of the processes stored and managed by the process management sub-systems 200, a notification/signal is communicated to the resource capacity model generator sub-system that a process change has occurred, which, in turn, triggers the generation of the resource capacity model within the resource capacity model generator sub-system 200.

In response to receiving notification of the change, the resource capacity model generator sub-system 200 receives automated data feeds from various data sources. Each data source may be specific to one or more entities (i.e., business units, frontline units or the like) within an enterprise. The data sources may include, but are not limited to, process-related measurable attribute data 410, otherwise referred to as process drivers. The measurable attribute data 410 may include volume-related data, such as the volume of occurrences of the process and/or sub-processes, tasks, activities or other work units associated with the process, which occur over predetermined time period s (e.g., hourly, daily, weekly or the like). In addition, the measurable attribute data 410 may include the volume of occurrences of ancillary events associated with the process (e.g., volume of process errors, volume of process issues or the like).

In addition, the data sources include processor data 420, including, but not limited to, processor function data 420-1 which defines the functions/capabilities of processors (e.g., employees, associates and the like) by the title assigned to the processor. Additionally, the processor data 420 includes processor and processor hierarchy data 420-1, which includes processor profiles of specific processors and resource (i.e., financial) hierarchy data that defines resource rates (i.e., cost) for different types of processors and/or specific processors.

Additionally, the data sources include taxonomy data 430 which classifies the various steps (e.g., sub-processes, activities/tasks and the like) of a process as a means of normalizing the steps for the purposes of capacity consideration.

In additional embodiments of the invention, the resource capacity model generator sub-system 200 may receive inputs, such as user inputs or the like, that define process dimensions, otherwise referred to as filters, for creating resource capacity models specific to the dimensions/filters. For example, the dimensions may indicate a specific geographic region (e.g., country, state, city, or the like) in which the process occurs, a specific computing platform on which the process occurs, specific entities associated with or controlling the process or the like. In this regard, resource capacity model generator sub-system may be configured to provide for a user portal that includes user interfaces for inputting the dimension/filter data.

Additionally, (as indicating by the dotted lines within the resource capacity model generator sub-system 300 block) the resource capacity model generator sub-system 300 may be modularized to accommodate differences in data and process management sub-system between different entities (e.g., business units, frontline units or the like) within an enterprise. Such modularization provides for these differences to be accounted for without effecting the overall consistency of the resulting resource capacity models.

In addition, the resource capacity model generator sub-system 300 is configured to receive automated feeds of resource (i.e., financial) data 450, which provides an indication of resource value to all steps of a process, including the resources (i.e., costs) associated with specific processors (e.g., hourly rates for specific employees/associates and the like). In this regard, the medium of exchange data 450 can be applied to and/or incorporated within the resource capacity model 340 to provide an overall resource (i.e., financial) forecast for the resource capacity model 450.

Further, the resource capacity model generator sub-system 300 is configured to aggregate the data and generate resource capacity models 340. Moreover, the resource capacity model generator sub-system 300 includes a presentation layer that is configured to present at least portions of the resource capacity models 340 in user interfaces 350 of resource capacity model portal/hub or the like. In addition, the resource capacity model generator sub-system 300 is configured to generate and initiate communication of electronic reports/medium of exchange statements (i.e., billing statements) 360, which may include at least portions of the resource capacity models 340. The user interfaces 350 and/or the reports 360 may be configured to provide access (such as user-activatable hyperlinks or the like) to the data used to compile the resource capacity model 340, as well as, the process change that precipitated the generation of the resource capacity model 340. As such, total transparency is afforded the user as to why the resource capacity model was generated and how the resource capacity model was generated.

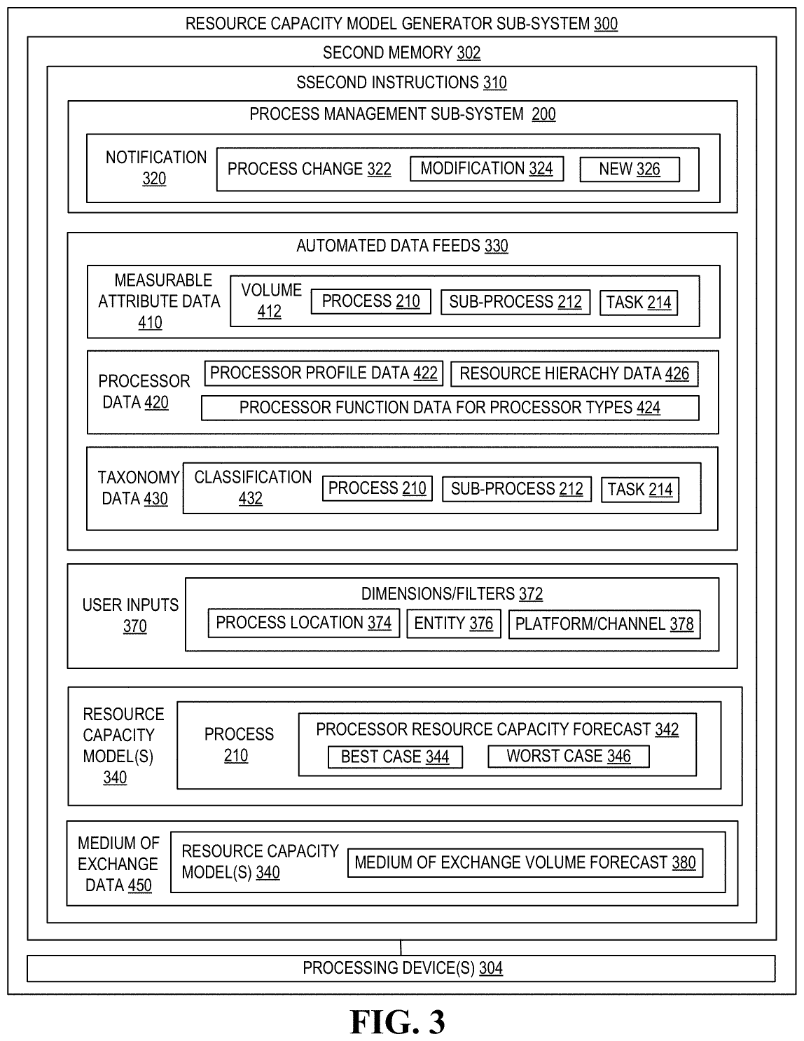

FIG. 3 depicts a block diagram of the resource capacity model generator sub-system 300 for generating singular automated resource capacity models, in accordance with various embodiments of the present invention. The resource capacity model generators sub-system includes a computing platform, which may comprise one or typically more computing devices (e.g., servers or the like) and is configured to execute instructions, such as algorithms, modules, routines, applications and the like. Resource capacity model generator sub-system 300 includes second memory 302 and the like which may comprise volatile and non-volatile memory, such as read-only and/or random-access memory (RAM and ROM), EPROM, EEPROM, flash cards, or any memory common to computing platforms). Moreover, second memory 302 and the like may comprise cloud storage, such as provided by a cloud storage service and/or a cloud connection service.

Further, resource capacity model generator sub-system 300 also includes at least one processing device 304, or the like which may be an application-specific integrated circuit (“ASIC”), or other chipset, logic circuit, or other data processing device. Processing device(s) 304 or the like may execute one or more application programming interface (APIs) (not shown in FIG. 3) that interface with any resident programs, such as second instructions 310 or the like stored in the second memory 302 of the resource capacity model generator sub-system 300 and any external programs. Processing device(s) 304 may include various processing subsystems (not shown in FIG. 3) embodied in hardware, firmware, software, and combinations thereof, that enable the functionality of the resource capacity model generator sub-system 300 and the operability of the resource capacity model generator sub-system 300 on the distributed communication network 110 (shown in FIG. 1). For example, processing subsystems allow for initiating and maintaining communications and exchanging data with other networked devices, such as data financial transaction database 200 and process management sub-system(s) 200 and capacity model-related data sources 200 (shown in FIG. 1). For the disclosed aspects, processing subsystems of system 100 may include any processing subsystem used in conjunction with second instructions 310 and related tools, routines, sub-routines, algorithms, sub-algorithms, sub-modules thereof.

Resource capacity model generator sub-system 300 may additionally include a communications module (not shown in FIG. 3) embodied in hardware, firmware, software, and combinations thereof, that enables electronic communications between the resource capacity model generator sub-system 300 and other network devices, such as, but not limited to, devices associated with process management sub-system(s) 200 and capacity model-related data sources 200 (shown in FIG. 1). Thus, communication module may include the requisite hardware, firmware, software and/or combinations thereof for establishing and maintaining a network communication connection with one or more network devices.

The memory 302 of resource capacity model generator sub-system 300 includes second instructions 310 that are executable by the processing device(s) 304 and configured to receive a notification/signal 320, from a process management sub-system 200 of the occurrence of a process change 322. The process change may comprise a modification 324 to an existing process or the generation of a new 326 process.

In response to receiving the notification 320, second instructions 310 are configured to receive automated data feeds 330 from capacity model-related data sources 400 (shown in FIG. 1). In specific embodiments of the invention, the second instructions 310 may be configured to communicate data requests to the various data sources 400, while in other embodiments of the invention, the process management sub-system(s) 200 may be configured to notify the various data sources 400 of the process change 322, which in turn triggers the data sources 400 to compile and communicate the requisite data to the resource capacity model generator sub-system 300 in an associated automated data feed 330.

The data feeds 330 are configured to include measurable attribute data 410 associated with the process. In specific embodiments of the system, the measurable attribute data 410, otherwise referred to as process driver data, includes, but is not limited to, volume-related data 412 that indicates the volume of occurrences of a process 210 and/or sub-processes 212, tasks/activities 214 or other function associated with the process, occurring over a predetermined time period (e.g., hour, day, week or the like).

Further, the data feeds 330 are configured to include processor (e.g., employee, associate or the like) data 420 or the like associated with processors required to perform the process 210 and/or sub-processes 212, activities/tasks 214 and the like. Processor data 420 may include, but is not limited to, processor summary data 422, resource hierarchy data 426 associated with processor types (billing rates for particular types of processors) and processor function data 424 that defines the functions performed by specific processor types.

Additionally, data feeds 330 are configured to include taxonomy data 430 that provides a classification 4532 for the various sub-processes 212 and tasks/activities 214 included within a process 210 as a means of normalizing the sub-processes 212 and/or task/activities 210 required to perform the process 210.

In optional embodiments of the invention, the second instructions 310 are configured to receive user inputs 370 that define dimensions/filters 372 for the resource capacity models 340. The dimensions/filters 372 may include, but are not limited to, geo-location 374 of the process, entity 376 associated with the process, computing platform/channel 376 on which the process is performed or the like.

In addition, second instructions 310 are configured to aggregate at least the measurable attribute data 410, the processor data 420, the taxonomy data 430 and in some embodiments of the invention, the dimensions/filters 372 to update an existing resource capacity model 340 or generate a new resource capacity model 340 that includes a process capacity forecast 342 for one or more future periods of time. In specific instances, the resource capacity model 340 may include a best case model (lowest forecast amount of capacity) and a worst case model (highest forecast amount of capacity).

In further optional embodiments of the invention, second instructions 310 are configured to receive medium of exchange data 450, such as resource rates for specific processors (e.g., Cost rates for specific employees/associates or the like) and determine, based on the medium of exchange data 450, medium of exchange values/volume forecasts 380 for all of the activities/tasks in the resource capacity model 340.

Referring to FIG. 7, a flow diagram is presented of a method 500 for generating singular r automated resource capacity models, in accordance with embodiments of the present invention. At Event 510, a notification/signal is received from a process management application that indicates that a change to a one of plurality of predetermined processes has occurred. The change may comprise a modification/update to an existing process or the addition of a new process.

At Event 520, in response to receiving the notification, the receipt of automated data feeds of process-related data is triggered. The process-related data may include, but is not limited to, (i) measurable-attribute data, such as, volume-related data associated with the process or specific activities/tasks/steps within the process or events ancillary to the process; (ii) processor data (i.e., employee, associate data) required to perform specific activities/tasks/steps within the process, such as, processor function data, processor summary data and resource (i.e., cost) hierarchy data associated types of processors; and (iii) taxonomy data that classifies the various sub-processes and tasks/activities included within the process.

At optional Event 530, one or more inputs are received, such as user inputs, that define dimensions/filters for the capacity model(s). The dimensions/filters may include, but are not limited to, geo-location of the process (i.e., country, state, city, zip code or the like), entity, such as legal entity or the like associated with the process, computing platform/channel associated with the process or the like.

At Event 540, one or more resource capacity models are updated or generated based at least on the (i) measurable attribute data, (ii) the processor data, (iii) the taxonomy data and, optionally, (iv) the dimension(s). The resource capacity models provide for forecast of performing the process for a future designated period of time.

At optional Event 550, an automated feed is received of medium of exchange data (i.e., financial data) associated with processors required to perform the process (e.g., hourly billing rates or the like) and, at optional Event 560, medium of exchange volume forecasts (cost forecasts) are determined for each resource capacity model based on the medium of exchange data.

At optional Event 570, user interfaces are updated/generated and/or reports/medium of exchange statements are generated and communicated to designated parties that include at least a portion of the resource capacity models and provide access to (e.g., user activatable links or the like) to the data used to generate the capacity model(s) and the process change that triggered the capacity model.

Thus, present embodiments of the invention as described above provide for end-to-end automated generation of resource capacity models. The system is integrated with process management systems, such that when a change to specified process occurs it triggers the generation of a new or updated capacity model. In addition, the system is integrated with multiple different data sources/applications, such that, once generation of a resource capacity model is triggered automated data feeds from the multiple data source/application occur and the system compiles and/or aggregates the data to create the resulting resource capacity models. Such data source/applications may include, but are not limited to, measurable attributes associated with the process, processor data and taxonomy data that classify tasks included with the overall process.

The features, functions, and advantages that have been discussed may be achieved independently in various embodiments of the present invention or may be combined with yet other embodiments, further details of which can be seen with reference to the following description and drawings.

Those skilled in the art may appreciate that various adaptations and modifications of the just described embodiments can be configured without departing from the scope and spirit of the invention. Therefore, it is to be understood that, within the scope of the appended claims, the invention may be practiced other than as specifically described herein.

What is claimed is:

1. A system for generating singular automated resource capacity models, the system comprising:
at least one process management sub-system including a first memory and at least one first processor in communication with the first memory, wherein in the first memory stores a plurality of predetermined processes and first instructions that are executable by the at least one first processor and configured to manage changes to the plurality of predetermined processes; and
a resource capacity model generator sub-system in network communication with the at least one process management sub-system, wherein the process resource capacity model generator sub-system includes a second memory and at least one second processor in communication with the second memory, wherein the second memory stores second instructions configured to:
receive, from the at least one process management sub-system, a notification of a change to a process from amongst the plurality of predetermined processes,
in response to receiving the notification, receive automated feeds of (i) measurable attribute data associated with the process, (ii) processor data associated with processors required to perform the process, and (iii) taxonomy data that classifies tasks associated with the process, and
update or generate one or more resource capacity models for the process based at least on the measurable attribute data, the processor data and the taxonomy data, wherein the resource capacity models forecast processor capacity for performing the process during at least one processing period.

2. The system of claim 1, wherein the second instructions are further configured to:
receive medium of exchange data, and
based on the medium of exchange data, correlate processors with an amount of resources required to perform at least one of sub-processes and tasks included within the process.

3. The system of claim 2, wherein the second instructions are further configured to:
determine at least one medium of exchange volume forecast for each of the one or more resource capacity models based at least on the medium of exchange data.

4. The system of claim 3, wherein the second instructions are further configured to:
generate at least one of user interfaces, and electronic reports, wherein the user interfaces and electronic reports are configured to present the one or more updated or generated resource capacity models.

5. The system of claim 4, wherein the second instructions configured to generate at least one of the user interfaces, and the electronic reports, wherein the user interfaces and the electronic reports are further configured to provide access to (i) the measurable attribute data, (ii) the processor data, and (iii) the taxonomy data used as a basis for updating or generating the one or more resource capacity models.

6. The system of claim 1, wherein the second instructions configured to receive, from the at least one process management sub-system, the notification of the change to the process further define the change as (i) addition of a new process, or (ii) modification of an existing process.

7. The system of claim 1, wherein the second instructions configured to receive automated feeds of (i) the measurable attribute data associated with the process, wherein the measurable attribute data includes a volume of at least one of the process or at least one of the tasks included within the process occurring within in at least one predetermined time interval.

8. The system of claim 1, wherein the second instructions are further configured to: in response to receiving the notification, receive inputs that define one or more dimensions for the one or more resource capacity models, and
wherein the second instructions are further configured to update or generate the one or more resource capacity models for the process based further on the one or more dimensions.

9. The system of claim 8, wherein the second instructions configured to receive the inputs that define the one or more dimensions, wherein the one or more dimensions include at least one of (i) geo-physical location of the process, (ii) entity associated with the process, and (iii) computing platform associated with the process.

10. The system of claim 1, wherein the second instructions configured to receive automated feeds of (ii) the processor data associated with the processors required to perform the process, wherein processor data includes at least one of (a) processor summary data that define functionality of processors, (b) at least one of a volume of processors or level of processors required to perform a task included within the process, and (c) resource hierarchy data that defines a resource rate for processors.

11. The system of claim 1, wherein the processor resource capacity model generator sub-system is modularized so as to receive the automated feeds of (i) the measurable attribute data (ii) the processor data and (iii) the taxonomy data from a plurality of entities associated with at least one of the process or the data.

12. The system of claim 1, wherein the second instructions configured to update or generate one or more resource capacity models for the process, wherein the one or more resource capacity models include a best-case resource capacity model and a worst-case capacity model.

13. A computer-implemented method for generating singular automated resource capacity models, the method implemented by one or more computing processor devices and comprising:
receiving a notification of a change to a process from amongst the plurality of predetermined processes;
in response to receiving the notification, receiving automated feeds of (i) measurable attribute data associated with the process, (ii) processor data associated with processors required to perform the process, and (iii) taxonomy data that classifies tasks associated with the process; and
updating or generating one or more resource capacity models for the process based at least on the measurable attribute data, the processor data and the taxonomy data, wherein the resource capacity models forecast processor capacity for performing the process during at least one processing period.

14. The computer-implemented method of claim 13, further comprising:
receiving an automated feed of medium of exchange data associated with the process; and
determining at least one medium of exchange volume forecast for each of the one or more resource capacity models based at least on the medium of exchange data.

15. The computer-implemented method of claim 13, further comprising:
generating at least one of user interfaces, and electronic reports, wherein the user interfaces and electronic reports are configured to present the one or more updated or generated resource capacity models and provide access to (i) the measurable attribute data, (ii) the processor data, and (iii) the taxonomy data used as a basis for updating or generating the one or more resource capacity models.

16. The computer-implemented method of claim 13, further comprising:
in response to receiving the notification, receiving inputs that define one or more dimensions for the one or more resource capacity models,
wherein updating or generating the one or more resource capacity models for the process is based further on the one or more dimensions, and
wherein the one or more dimensions include at least one of (i) geo-physical location of the process, (ii) entity associated with the process, and (iii) computing platform associated with the process.

17. A computer program product comprising:
a non-transitory computer-readable medium comprising:
a first set of codes for causing a computer to receive a notification of a change to a process from amongst the plurality of predetermined processes;
a second set of codes for causing a computer to, in response to receiving the notification, receive automated feeds of (i) measurable attribute data associated with the process, (ii) processor data associated with processors required to perform the process, and (iii) taxonomy data that classifies tasks associated with the process; and
a third set of codes for causing a computer to update or generate one or more resource capacity models for the process based at least on the measurable attribute data, the processor data and the taxonomy data, wherein the resource capacity models forecast processor capacity for performing the process during at least one processing period.

18. The computer program product of claim 17, wherein the non-transitory computer-readable medium further comprises:
a fourth set of codes for causing a computer to receive an automated feed of medium of exchange data associated with the process; and
a fifth set of codes for causing a computer to determine at least one medium of exchange volume forecast for each of the one or more resource capacity models based at least on the medium of exchange data.

19. The computer program product of claim 17, wherein the non-transitory computer-readable medium further comprises:
a fourth set of codes for causing a computer to generate at least one of user interfaces, and electronic reports, wherein the user interfaces and electronic reports are configured to present the one or more updated or generated resource capacity models and provide access to (i) the measurable attribute data, (ii) the processor data, and (iii) the taxonomy data used as a basis for updating or generating the one or more resource capacity models.

20. The computer program product of claim 17, wherein the non-transitory computer-readable medium further comprises:
a fourth set of codes for causing a computer to, in response to receiving the notification, receive inputs that define one or more dimensions for the one or more resource capacity models,
wherein the third set of codes is further configured to update or generate the one or more resource capacity models for the process based further on the one or more dimensions, and
wherein the one or more dimensions include at least one of (i) geo-physical location of the process, (ii) entity associated with the process, and (iii) computing platform associated with the process.
